(19) United States
(12) Patent Application Publication
(10) Pub. No.: US 2025/0234606 A1
(43) Pub. Date: Jul. 17, 2025

(54) COMPLEMENTARY FIELD-EFFECT TRANSISTORS AND METHODS FOR FORMING THE SAME

(71) Applicant: Tokyo Electron Limited, Tokyo (JP)

(72) Inventor: Eric Chih-Fang LIU, Albany, NY (US)

(73) Assignee: Tokyo Electron Limited, Tokyo (JP)

(21) Appl. No.: 18/414,262

(22) Filed: Jan. 16, 2024

(51) Int. Cl. H01L 29/06; H01L 21/8238; H01L 27/092; H01L 29/08; H01L 29/423; H01L 29/66; H01L 29/775; H01L 29/786

(52) U.S. Cl. CPC H10D 62/121; H10D 30/014; H10D 30/43; H10D 30/6735; H10D 30/6757; H10D 62/151; H10D 64/017; H10D 84/0167; H10D 84/0184; H10D 84/038; H10D 84/85

(57) ABSTRACT

A semiconductor device includes a plurality of first nanostructures extending along a first lateral direction with a first length, and spaced from one another along a vertical direction. The semiconductor device includes a plurality of second nanostructures extending along the first lateral direction with a second length, and spaced from one another along the vertical direction. The semiconductor device includes a dielectric layer interposed between the plurality of first nanostructures and the plurality of second nanostructures along the vertical direction. The second length is different from the first length.

### FIELD OF THE DISCLOSURE

This disclosure relates to semiconductor devices, and more particularly, to a complementary field-effect transistor and a method for forming the same.

### BACKGROUND

Fabrication of semiconductor devices relies on execution of various fabrication processes that are performed repeatedly in order to form desired semiconductor features on a substrate. In the recent years, scaling down semiconductor devices became more challenging as sizes of features reached single digit nanometer range.

In the manufacture of semiconductor devices, various fabrication processes are executed, for example, film-forming depositions, etch mask creation, patterning, material etching and removal, and doping treatments, among others. These processes can be performed repeatedly to form desired semiconductor device elements on a substrate. Historically, transistors have been created in one plane, with wiring or metallization formed above the active device plane, and have thus been characterized as two-dimensional (2D) circuits or 2D fabrication. Scaling efforts have greatly increased the number of transistors per unit area in 2D circuits, yet scaling efforts are running into greater challenges as scaling enters single digit nanometer semiconductor device fabrication nodes.

### SUMMARY

One aspect of the present disclosure is directed to a semiconductor device. The semiconductor device includes a plurality of first nanostructures extending along a first lateral direction with a first length, and spaced from one another along a vertical direction. The semiconductor device includes a plurality of second nanostructures extending along the first lateral direction with a second length, and spaced from one another along the vertical direction. The semiconductor device includes a dielectric layer interposed between the plurality of first nanostructures and the plurality of second nanostructures along the vertical direction. The second length is different from the first length.

In some embodiments, the semiconductor device includes a gate structure extending along a second lateral direction perpendicular to the first lateral direction. The gate structure includes a first portion wrapping around each of the plurality of first nanostructures and a second portion wrapping around each of the plurality of second nanostructures. Along the vertical direction, the dielectric layer is interposed between the first portion of the gate structure and second portion of the gate structure.

In some embodiments, along the vertical direction, the dielectric layer is interposed between a topmost one of the plurality of first nanostructures and a bottommost one of the plurality of second nanostructures. The first length is longer than the second length.

In some embodiments, the semiconductor device includes a pair of first source/drain structures coupled to ends of the each of the first nanostructures along the first lateral direction, respectively; and a pair of second source/drain structures coupled to ends of the each of the second nanostructures along the first lateral direction, respectively. The first source/drain structures have a first conductive type, and the second source/drain structures have a second conductive type.

Another aspect of the present disclosure is directed to a semiconductor device. The semiconductor device includes a first transistor having a first conductive type and comprising a plurality of first nanostructures extending along a first lateral direction with a first length. The semiconductor device includes a second transistor having a second conductive type and comprising a plurality of second nanostructures extending along the first lateral direction with a second length. The second transistor is disposed over the first transistor along a vertical direction, and the second length is shorter than the first length.

In some embodiments, the first transistor and the second transistor share a gate structure extending along a second lateral direction perpendicular to the first lateral direction. The gate structure includes a first portion wrapping around each of the plurality of first nanostructures and a second portion wrapping around each of the plurality of second nanostructures.

In some embodiments, the semiconductor device includes a dielectric layer interposed between the first transistor and the second transistor along the vertical direction. Along the vertical direction, the dielectric layer is interposed between the first portion of the gate structure and second portion of the gate structure. Along the vertical direction, the dielectric layer is interposed between a topmost one of the plurality of first nanostructures and a bottommost one of the plurality of second nanostructures.

In some embodiments, the semiconductor device includes a pair of first source/drain structures coupled to ends of the each of the first nanostructures along the first lateral direction, respectively; and a pair of second source/drain structures coupled to ends of the each of the second nanostructures along the first lateral direction, respectively. The first source/drain structures have the first conductive type, and the second source/drain structures have the second conductive type.

Yet another aspect of the present disclosure is directed to a method for fabricating semiconductor devices. The method includes forming a stack including a first portion, a second portion, and a third portion arranged on top of one another, wherein the first portion includes a plurality of first layers having a first semiconductor material and a plurality of second layers having a second semiconductor material alternately arranged on top of one another, the second portion includes an isolation layer having the second semiconductor material, and the third portion includes a plurality of third layers having the first semiconductor material and a plurality of fourth layers having the second semiconductor material alternately arranged on top of one another, and wherein the first layers, the second layers, the isolation layer, the third layers, and the fourth layers extend along a first lateral direction. The method includes forming a dummy gate structure to straddle the stack, wherein the dummy gate structure extends along a second lateral direction perpendicular to the first lateral direction. The method includes selectively etching the isolation layer, while leaving a first portion of each of the first, second, third, and fourth layers that is overlaid by the dummy gate structure substantially intact. The method includes replacing the dummy gate structure with an active gate structure.

In some embodiments, subsequently to the step of forming a dummy gate structure and prior to the step of selectively etching the isolation layer, the method includes forming a first gate spacer extending along sidewalls of the dummy gate structure; removing second portions of each of the third and fourth layers that extend beyond the first gate spacers along the first lateral direction; and forming a second gate spacer extending along the first gate spacer.

In some embodiments, subsequently to the step of selectively etching the isolation layer, the method includes depositing a dielectric material; removing second portions of each of the first and second layers that extend beyond the second gate spacer along the first lateral direction; and removing the second gate spacer.

In some embodiments, the step of replacing the dummy gate structure with an active gate structure further comprises removing the second layers and the fourth layers while leaving the first layers and the third layers substantially intact, such that the active gate structure wraps around each of the first layers and the third layers.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustrations and a further understanding of the various aspects and implementations, and are incorporated in and constitute a part of this specification. Aspects can be combined, and it will be readily appreciated that features described in the context of one aspect of the invention can be combined with other aspects. Aspects can be implemented in any convenient form. As used in the specification and in the claims, the singular form of “a,” “an,” and “the” include plural referents unless the context clearly dictates otherwise.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIG. 1 shows a flow chart of an example method for fabricating a semiconductor structure including a complementary field-effect transistor, according to various embodiments.

FIGS. 2-15 illustrate perspective views of an example semiconductor structure during various fabrication stages, made by the method of FIG. 1, according to various embodiments.

### DETAILED DESCRIPTION

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

Likewise, although the Figures and aspects of the disclosure may show or describe devices herein as having a particular shape, it should be understood that such shapes are merely illustrative and should not be considered limiting to the scope of the techniques described herein. For example, the techniques described herein may be implemented in any shape or geometry for any material or layer to achieve desired results. In addition, examples in which two transistors or devices are shown stacked on top of one another are shown for illustrative purposes only, and for the purposes of simplicity. Indeed, the techniques described herein may provide for one to any number of stacked devices. Further, although the devices fabricated using these techniques are shown as transistors, it should be understood that any type of electric electronic device may be manufactured using such techniques, including but not limited to transistors, variable resistors, resistors, and capacitors.

As part of the scaling efforts, gate-all-around field-effect transistors (GAAFETs) (e.g., nanowire-type GAAFETs or nanosheet-type GAAFETs) have been developed in order to improve drive current and electrostatics and to allow for device size scaling, increased device density and reduced area consumption. A GAAFET typically includes one or more elongated nanostructures (e.g., nanowire(s) or nanosheet(s)), which extend laterally between source/drain regions, and a wrap-around gate structure, which wraps around the nanostructures such that the nanostructures collectively function as a channel.

Recently, complementary field-effect transistors (CFETs) have been developed in order to further increase on-chip device density and reduce area consumption. A CFET typically includes a pair of N-type and P-type GAAFETs that are stacked on top of one another. For example, a CFET includes an N-type GAAFET on a first level, a P-type GAAFET on a second level (i.e., above or below), and a common gate that extends vertically across and wraps around the respective channels of the N-type and P-type GAAFETs. In existing technologies, no method readily available to effectively isolate the N-type and P-type GAAFETs, which can cause signals to cross-talk between the N-type and P-type GAAFETs. Accordingly, existing CFETs have not been entirely satisfactory in certain aspects.

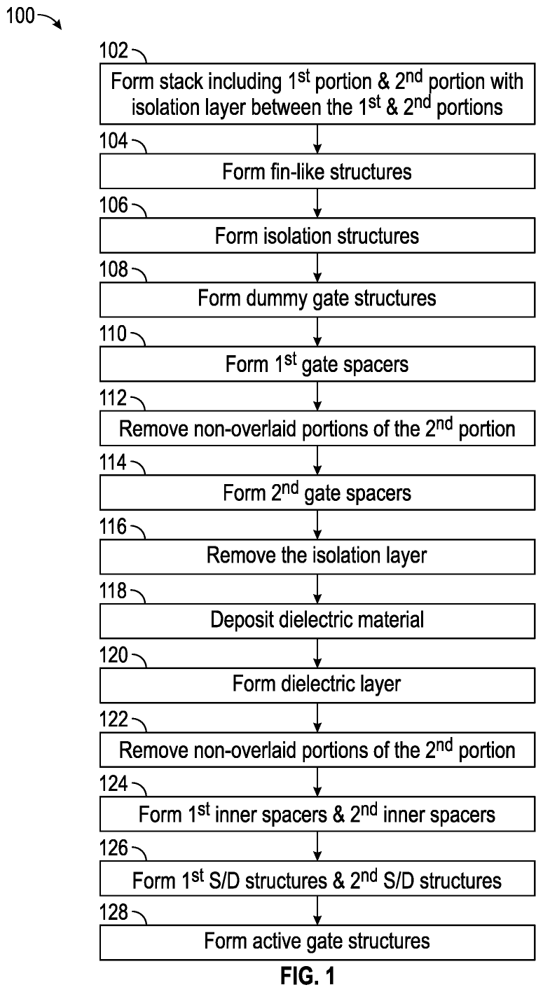

FIG. 1 illustrates a flow chart of an example method 100 for fabricating a semiconductor device, in accordance with various embodiments of the present disclosure. For example, the semiconductor device, made by the method 100, includes a complementary field-effect transistor (CFET) structure. The CFET structure includes a first transistor, with a first conductive type, that is formed in a first lower level and a second transistor, with a second conductive type, that is formed in a second higher level. Specifically, the lower first transistor may have its channel formed by a number of first nanostructures with a first length, and the upper second transistor may have its channel formed by a number of second nanostructure with a second length, where the first length is longer than the second length.

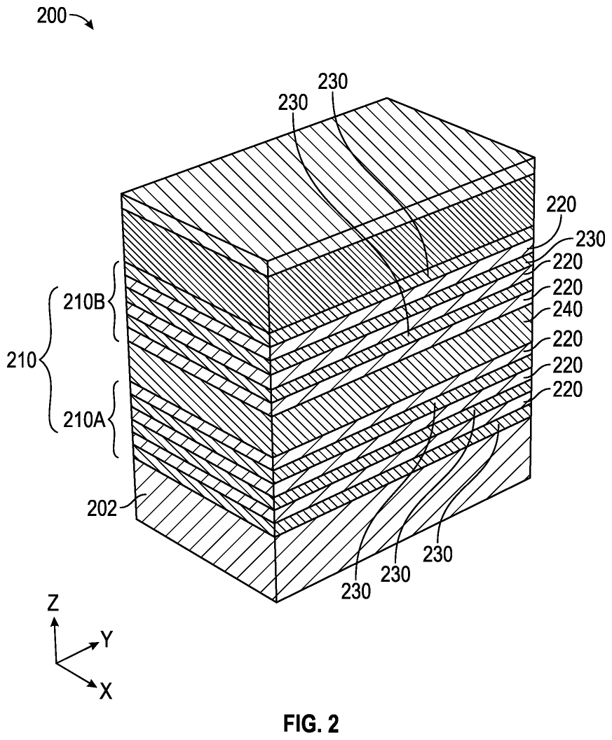

It is noted that the method 100 is merely an example, and is not intended to limit the present disclosure. Accordingly, it is understood that additional operations may be provided before, during, and after the method 100 of FIG. 1, and that some other operations may only be briefly described herein. In various embodiments, operations of the method 100 may be associated with perspective views of an example CFET structure at various fabrication stages as shown in FIGS. 2 to 15, respectively, which will be discussed in further detail below. It should be understood that the CFET structure, shown in FIGS. 2 to 15, may include a number of other devices such as inductors, fuses, capacitors, coils, etc., while remaining within the scope of the present disclosure.

Corresponding to operation 102 of FIG. 1, FIG. 2 is a perspective view of a CFET structure 200 in which a stack 210 is formed over a substrate 202, in accordance with various embodiments. In the illustrated embodiment of FIG. 2, the stack 210 has a first side extending along a first lateral direction (the Y-direction) and a second side extending along a second lateral direction (the X-direction). The first lateral direction (the Y-direction) and the second lateral direction (the X-direction) can correspond to a channel width direction and a channel length direction of transistors of the CFET structure 200, respectively, which will be discussed in further detail below.

The substrate 202 may be a semiconductor substrate, such as a bulk semiconductor, a semiconductor-on-insulator (SOI) substrate, or the like, which may be doped (e.g., with a p-type or an n-type dopant) or undoped. The substrate 202 may be a wafer, such as a silicon wafer. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 202 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GalnAs, GaInP, and/or GaInAsP; or combinations thereof.

The stack 210 includes a plurality of first (e.g., blanket) semiconductor layers 220 and a plurality of second (e.g., blanket) semiconductor layers 230 alternately stacked on top of one another along a vertical direction (the Z-direction). In some embodiments, the stack 210 includes a first number of the first semiconductor layers 220 and a first number of the second semiconductor layers 230 formed as a first (e.g., lower) portion 210A, and a second number of the first semiconductor layers 220 and a second number of the second semiconductor layers 230 formed as a second (e.g., upper) portion 210B. In some embodiments, the first number may be equal to the second number. For example, in FIG. 2, the first portion of the stack 210A has 3 first semiconductor layers 220 and 3 second semiconductor layers 230 alternately stacked on top of one another; and the second portion of the stack 210B has 3 first semiconductor layers 220 and 3 second semiconductor layers 230 alternately stacked on top of one another. It should be understood that the stack 210 can include any number of first semiconductor layers and any number of second semiconductor layers, while remaining within the scope of the present disclosure.

The two semiconductor layers 220 and 230 have different compositions. In various embodiments, the two semiconductor layers 220 and 230 have compositions that provide for different oxidation rates and/or different etch selectivity between the layers. In an embodiment, the second semiconductor layers 230 include silicon germanium (Si₁₋ₓGeₓ), and the first semiconductor layers 220 include silicon (Si). For example, each of the second semiconductor layers 230 is Si₁₋ₓGeₓ that includes less than 50% (x<0.5) Ge in molar ratio. For example, Ge may comprise about 15% to 35% of the second semiconductor layers 230 of Si₁₋ₓGeₓ in molar ratio. Either of the semiconductor layers 220 and 230 may include other materials, for example, a compound semiconductor such as silicon carbide, gallium arsenide, gallium phosphide, indium phosphide, indium arsenide, and/or indium antimonide, an alloy semiconductor such as GaAsP, AlInAs, AlGaAs, InGaAs, GaInP, and/or GaInAsP, or combinations thereof. The materials of the semiconductor layers 220 and 230 may be chosen based on providing differing oxidation rates and/or etch selectivity.

Further, the stack 210 includes an isolation layer 240 vertically interposed between the lower portion 210A and the upper portion 210B, in accordance with various embodiments of the present disclosure. For example, the isolation layer 240 is vertically interposed between a topmost one of the first semiconductor layers of the lower portion 210A and a bottommost one of the first semiconductor layers of the upper portion 210B. In various embodiments, the isolation layer 240 and the second semiconductor layers 230 may be formed of the same material, e.g., Si₁₋ₓGeₓ.

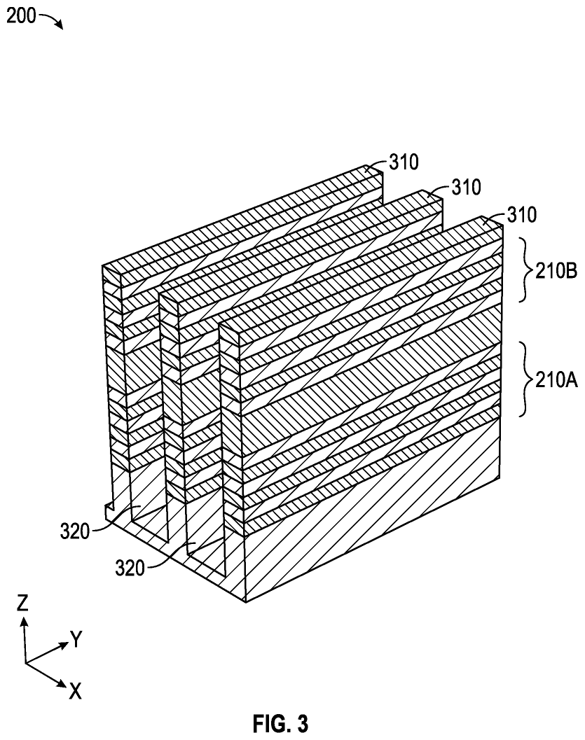

Corresponding to operation 104 of FIG. 1, FIG. 3 is a perspective view of the CFET structure 200 in which a number of fin-like structures 310 are formed in the stack 210, in accordance with various embodiments. In the illustrated embodiment of FIG. 3, each of the fin-like structures 310 extends along the Y-direction.

The fin-like structures 310 are formed by patterning the stack 210 (FIG. 2) using, for example, photolithography and etching techniques. For example, a mask layer (which can include multiple layers such as, for example, a pad oxide layer and an overlying pad nitride layer) is formed over the topmost second semiconductor layer 230 of the second portion 210B. The pad oxide layer may be a thin film comprising silicon oxide formed, for example, using a thermal oxidation process. The pad oxide layer may act as an adhesion layer between the topmost second semiconductor layer 230 and the overlying pad nitride layer. In some embodiments, the pad nitride layer is formed of silicon nitride, silicon oxynitride, silicon carbonitride, the like, or combinations thereof. The pad nitride layer may be formed using low-pressure chemical vapor deposition (LPCVD) or plasma enhanced chemical vapor deposition (PECVD), for example.

The mask layer may be patterned using photolithography techniques. Generally, photolithography techniques utilize a photoresist material (not shown) that is deposited, irradiated (exposed), and developed to remove a portion of the photoresist material. The remaining photoresist material protects the underlying material, such as the mask layer in this example, from subsequent processing steps, such as etching. For example, the photoresist material is used to pattern the pad oxide layer and pad nitride layer to form a patterned mask.

The patterned mask can be subsequently used to pattern exposed portions of the stack 210 to form trenches (or openings) 320, thereby defining the fin-like structures 310, each of which is interposed between adjacent trenches 320 along the X-direction. When multiple fin-like structures 310 are formed, such a trench 320 may be disposed between any adjacent ones of the fin structures, as shown in the example of FIG. 3. In some embodiments, the fin-like structures 310 are formed by forming trenches (e.g., 320) in the semiconductor layers 220-230 using, for example, reactive ion etch (RIE), neutral beam etch (NBE), the like, or combinations thereof. The etch may be anisotropic. Accordingly, each of the fin-like structures 310 can have its respective lower portion 210A and upper portion 210B, with the isolation layer 240 vertically interposed therebetween.

In some embodiments, the trenches 320 may be strips (when viewed from the top) parallel to each other, and closely spaced with respect to each other. In some embodiments, the trenches 320 may be continuous and surround the fin-like structure 310. Further, the trenches 320 can extend further below the bottommost second semiconductor layer 230 of the lower portion 210A, e.g., extending into the substrate 202, as shown in FIG. 3. Stated another way, further below the lower portion 210A that is formed by some of the alternately stacked semiconductor layers 220-230, each of the fin-like structures 310 can have a foundation portion formed by the substrate 202.

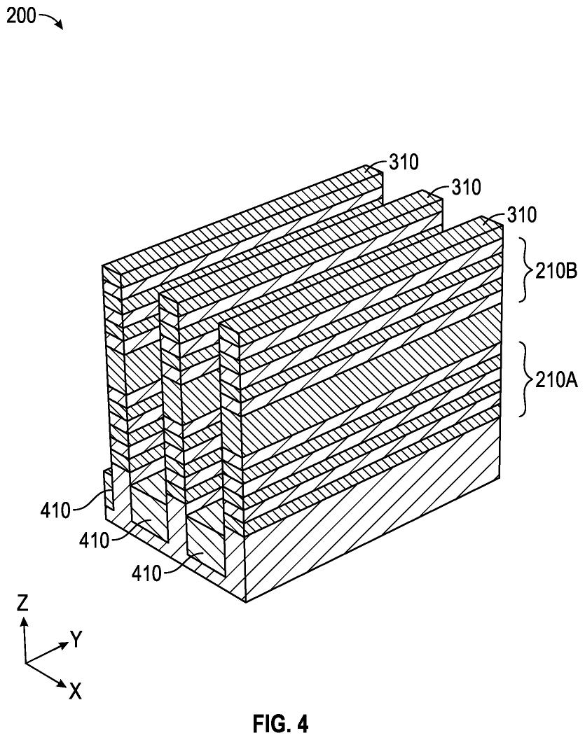

Corresponding to operation 106 of FIG. 1, FIG. 4 is a perspective view of the CFET structure 200 in which a number of isolation structures 410 are formed, in accordance with various embodiments. In the illustrated embodiment of FIG. 4, each of the isolation structures 410 at least has a portion extending along the Y-direction.

Each of the isolation structure 410, which can include multiple portions, may be formed between adjacent fin-like structures, or next to a single fin-like structure. The isolation structure 410, which is formed of an insulation material, can electrically isolate neighboring fin-like structures from each other. The insulation material may be an oxide, such as silicon oxide, a nitride, the like, or combinations thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or combinations thereof. Other insulation materials and/or other formation processes may be used. In an example, the insulation material is silicon oxide formed by a FCVD process. An anneal process may be performed once the insulation material is formed. A planarization process, such as a chemical mechanical polish (CMP) process, may remove any excess insulation material and form a top surface of the insulation material and a top surface of a patterned mask (not shown) defining the fin-like structures 310. The patterned mask may also be removed by the planarization process, in various embodiments.

Next, the insulation material is recessed to form the isolation structure 410, as shown in the example of FIG. 4. Such an isolation structure is sometimes referred to as a shallow trench isolation (STI). The isolation structure 410 is recessed such that the fin-like structure 310 protrudes from between neighboring portions of the isolation structure 410. For example, in FIG. 4, the first (lower) portion and second (upper) portion of each of the fin-like structure 310 vertically extend above the top surface of the isolation structures 410. The top surface of the isolation structures (STIs) 410 may have a flat surface (as illustrated), a convex surface, a concave surface (such as dishing), or combinations thereof. The top surface of the isolation structure 410 may be formed flat, convex, and/or concave by an appropriate etch. The isolation structure 410 may be recessed using an acceptable etching process, such as one that is selective to the material of the isolation structure 410. For example, a dry etch or a wet etch using dilute hydrofluoric (DHF) acid may be performed to recess the isolation structure 410.

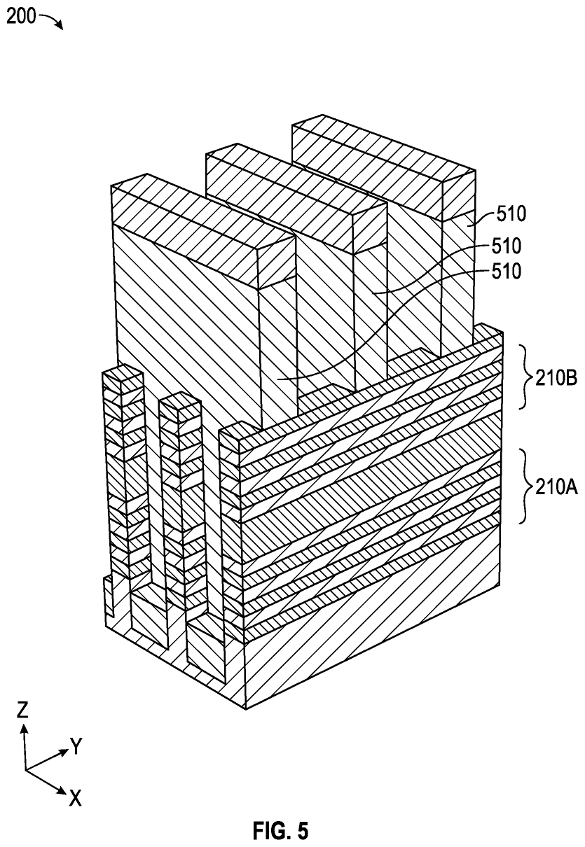

Corresponding to operation 108 of FIG. 1, FIG. 5 is a perspective view of the CFET structure 200 in which a number of dummy gate structures 510 are formed, in accordance with various embodiments. In the illustrated embodiment of FIG. 5, each of the dummy gate structures 510 extends along the X-direction, thereby traversing or otherwise straddling the fin-like structures 310.

The dummy gate structures 510 may each be placed where an active (e.g., metal) gate structure is later formed, in various embodiments. In some embodiments, the dummy gate structure 510 is placed over a portion of each of the fin-like structure 310. Such an overlaid portion of the fin-like structure 310 includes portions of the first semiconductor layers 220 that are later collectively formed as the conduction channel of a corresponding transistor, and portions of the second semiconductor layers 230 that are replaced with an active gate structure. As such, the active gate structure can wrap around each of the portions of the first semiconductor layers 220, which will be discussed in further detail below. Additionally, the non-overlaid portions of the fin-like structure 310 may be later removed (e.g., etched) and replaced with epitaxial source/drain structures.

In some embodiments, the dummy gate structure 510 can include one or more Si-based or SiGe-based materials. The dummy gate structure 510 may be deposited by CVD, PECVD, ALD, FCVD, or combinations thereof. Although the dummy gate structure 510 is shown as being formed as a single piece in the illustrated embodiment of FIG. 5, it should be understood that the dummy gate structure 510 can be formed to have multiple portions, each of which may include respective different materials, while remaining within the scope of the present disclosure.

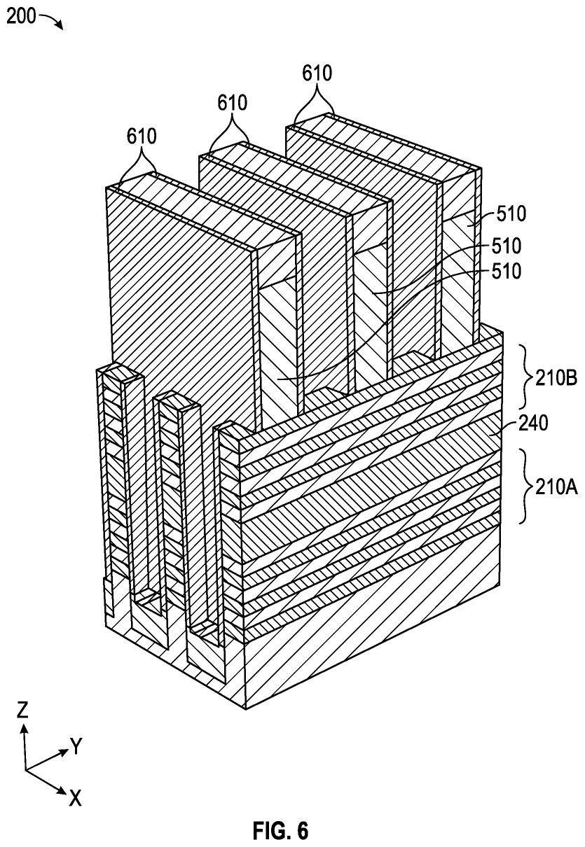

Corresponding to operation 110 of FIG. 1, FIG. 6 is a perspective view of the CFET structure 200 in which a pair of first gate spacers 610 are formed to extend along sidewalls of each of the dummy gate structures 510, respectively, in accordance with various embodiments.

The first gate spacers 610 may include a low-k dielectric material and may be formed of a suitable dielectric material, such as silicon oxide, silicon oxycarbonitride, or the like. Any suitable deposition method, such as thermal oxidation, chemical vapor deposition (CVD), or the like, may be used to form the first gate spacers 610.

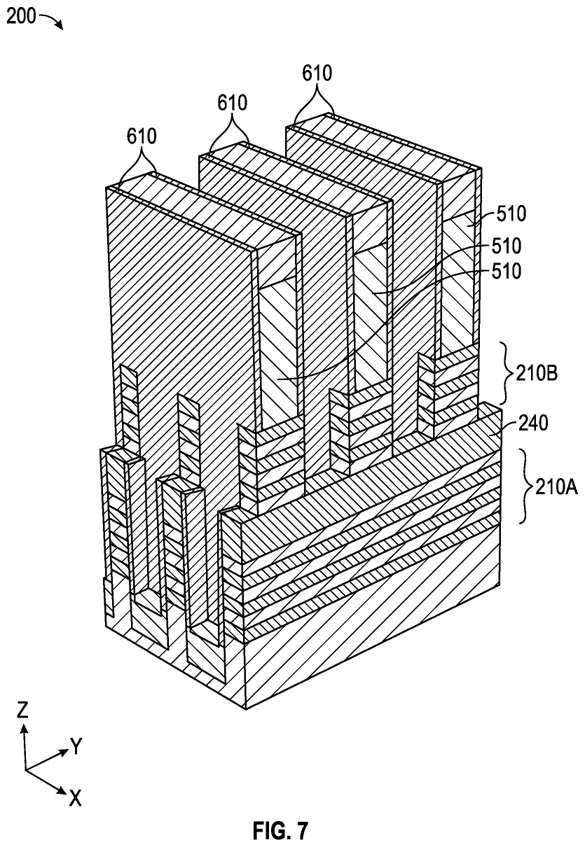

Corresponding to operation 112 of FIG. 1, FIG. 7 is a perspective view of the CFET structure 200 in which the non-overlaid portions of the upper portion of each of the fin-like structures 310 are removed, in accordance with various embodiments.

In some embodiments of the present disclosure, the dummy gate structure 510, together with the first gate spacers 610, can serve as a mask to etch the non-overlaid portions of the upper portion 210B of each of the fin-like structures 310. Such an etching process may stop at the isolation layer 240. As a result, along the Z-direction, newly formed sidewalls of the upper portion of each of the fin-like structures 310 are exposed and aligned with sidewalls of the first gate spacers 610. For example, in FIG. 7, the remaining portions of the semiconductor layers 220 and 230 of the upper portion 210B overlaid by the dummy gate structures 510 may sometimes be referred to as upper nanostructures (e.g., nanosheets) 220B and 230B, respectively.

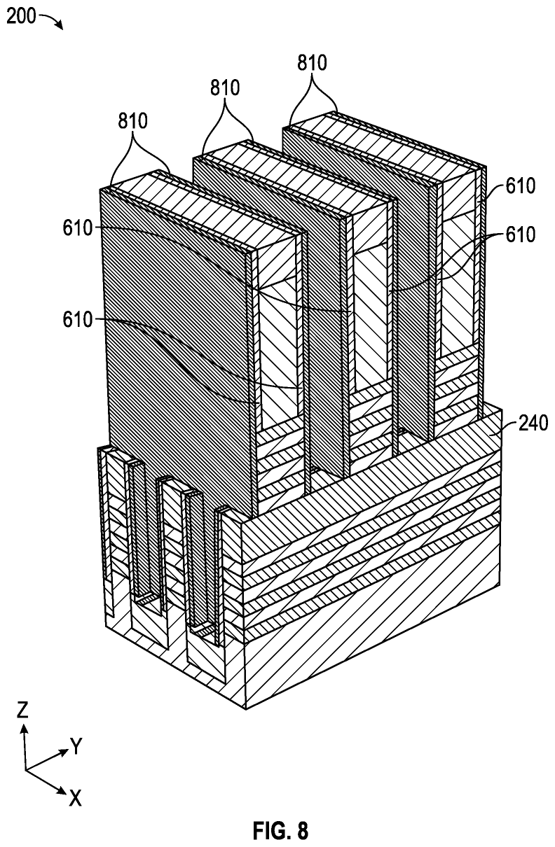

Corresponding to operation 114 of FIG. 1, FIG. 8 is a perspective view of the CFET structure 200 in which a pair of second gate spacers 810 are formed to extend along the sidewalls of the corresponding first gate spacers 610, respectively, in accordance with various embodiments.

The second gate spacers 810 may include a low-k dielectric material and may be formed of a suitable dielectric material, such as silicon oxide, silicon oxycarbonitride, or the like. In some embodiments, a substantially large etching selectivity is present between the material of the second gate spacers 810 and the material of the first gate spacers 610. Any suitable deposition method, such as thermal oxidation, chemical vapor deposition (CVD), or the like, may be used to form the second gate spacers 810. In some embodiments, the second gate spacers 810 can be formed to protect or otherwise cover the exposed sidewalls of the upper nanostructures 220B and 230B, while leaving the isolation layer 240 exposed.

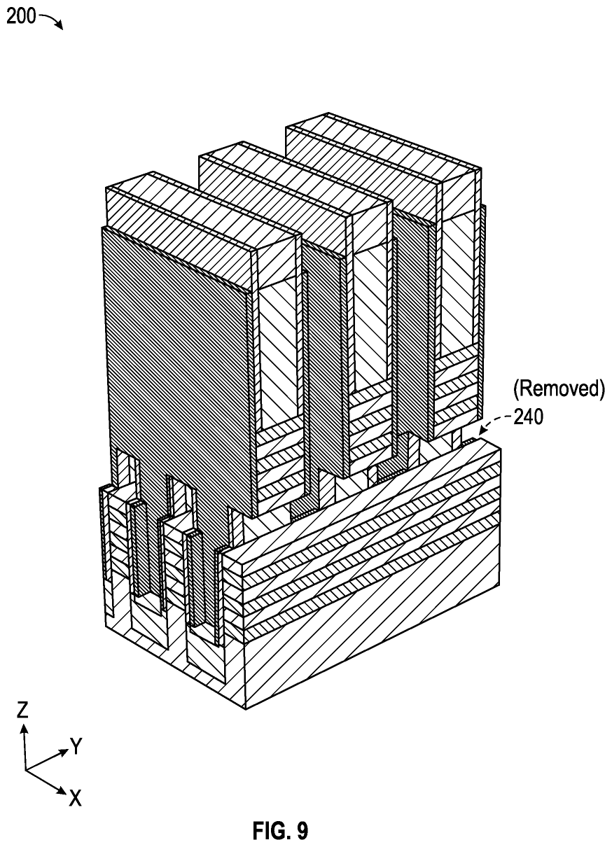

Corresponding to operation 116 of FIG. 1, FIG. 9 is a perspective view of the CFET structure 200 in which the exposed isolation layer 240 is removed, in accordance with various embodiments.

In some embodiments, the isolation layer 240 can be removed through an etching process that selectively removes the material of the isolation layer 240 (e.g., Si₁₋ₓGeₓ), while leaving other exposed material(s) substantially intact. For example, the second gate spacers 810 covers sidewalls of the upper nanostructures 230B (the second semiconductor layers 230 of the upper portion 210B), which are formed of the similar material to the isolation layer 240. Further, the topmost second semiconductor layers 230 of the lower portion 210A and the bottommost second semiconductor layers 230 of the upper portion 210B are protected by respective first semiconductor layers 220. As such, the isolation layer 240 can be removed, while the second semiconductor layers 230 in each of the lower portion 210A and the upper portion 210B can remain substantially intact.

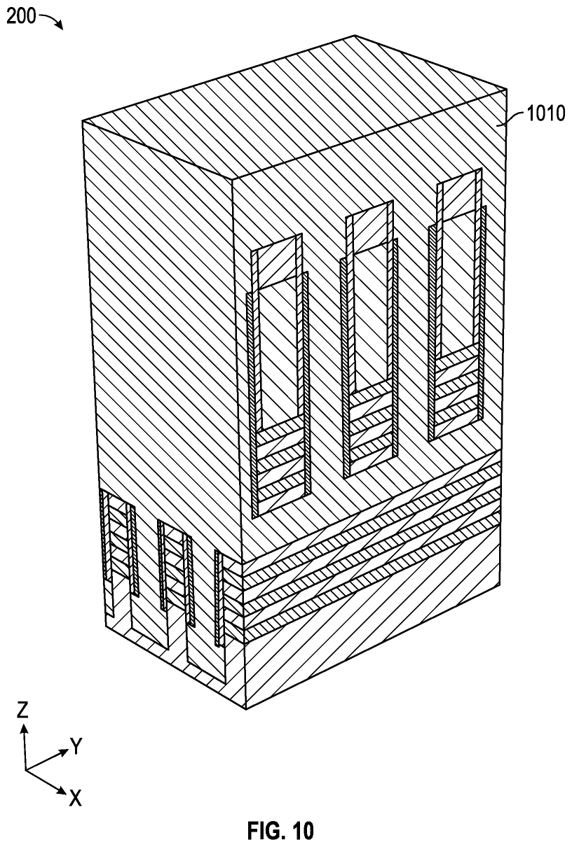

Corresponding to operation 118 of FIG. 1, FIG. 10 is a perspective view of the CFET structure 200 in which a dielectric material 1010 is deposited over the workpiece, in accordance with various embodiments.

The dielectric material 1010 may be an oxide, such as silicon oxide, a nitride, the like, or combinations thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or combinations thereof. Other dielectric materials and/or other formation processes may be used. In an example, the dielectric material is silicon oxide formed by a FCVD process. An anneal process may be performed once the dielectric material is formed. In some embodiments, the dielectric material 1010 can at least fill up the opening formed by removing the isolation layer 240. That is, the dielectric material 1010 is vertically interposed between the lower portion 210A and the upper portion 210B of each of the fin-like structures 310.

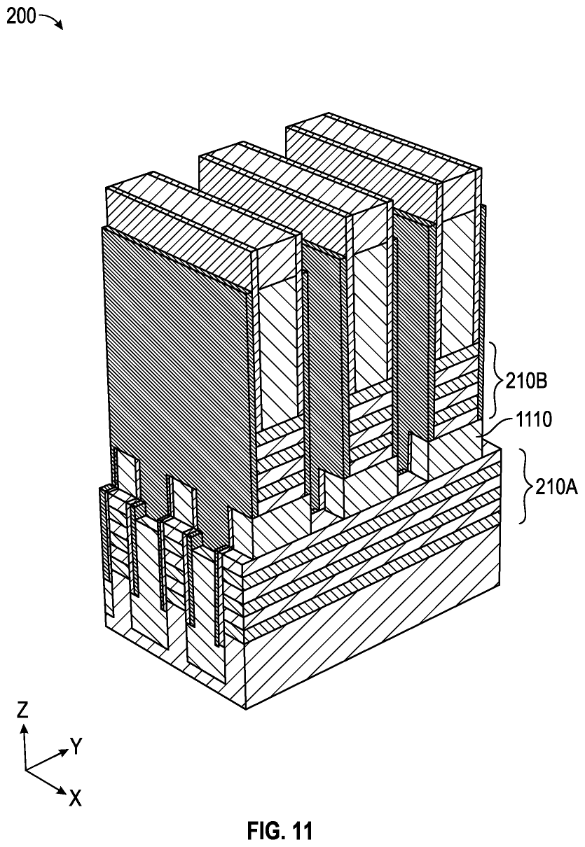

Corresponding to operation 120 of FIG. 1, FIG. 11 is a perspective view of the CFET structure 200 in which a dielectric layer 1110 is formed between the lower portion 210A and the upper portion 210B, in accordance with various embodiments.

The dielectric layer 1110 is formed by recessing the dielectric material 1010. Such a recessing process may include any acceptable etching process, such as one that is selective to the material of the dielectric material 1010, with respect to other exposed materials such as, for example, the second gate spacers 810, the first semiconductor layers 220, etc. As a non-limiting example, a dry etch or a wet etch using dilute hydrofluoric (DHF) acid may be performed to recess the dielectric material 1010. In some embodiments, the dummy gate structures 510, together with the first gate spacers 610 and the second gate spacers 810, may serve as a mask to recess the dielectric material 1010, and such a recessing process may stop when the topmost first semiconductor layers 220 of the lower portions 210A are exposed.

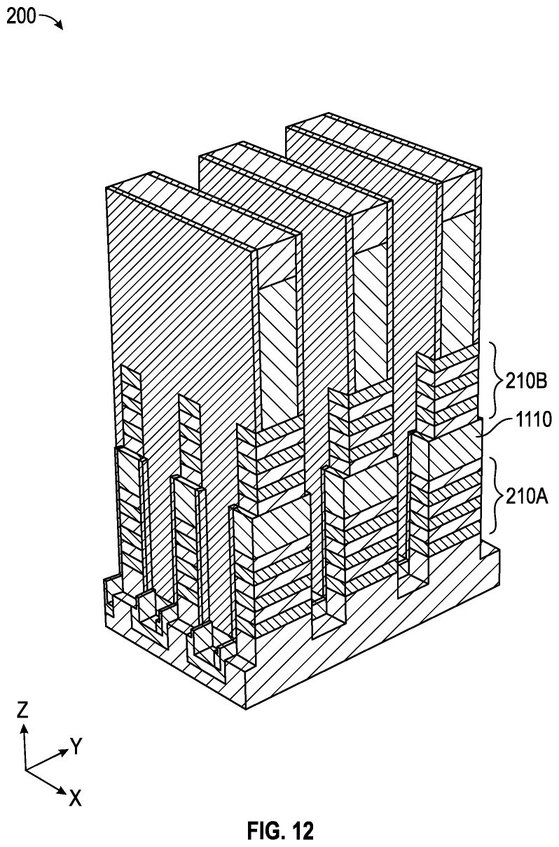

Corresponding to operation 122 of FIG. 1, FIG. 12 is a perspective view of the CFET structure 200 in which the non-overlaid portions of the lower portion of each of the fin-like structures 310 are removed, in accordance with various embodiments.

In some embodiments of the present disclosure, the dummy gate structure 510, together with the first gate spacers 610 and the second gate spacers 810, can serve as a mask to etch the non-overlaid portions of the lower portion 210A of each of the fin-like structures 310. Such an etching process may stop as the isolation structures 410 are exposed. As a result, along the Z-direction, newly formed sidewalls of the lower portion of each of the fin-like structures 310 are exposed and aligned with sidewalls of the second gate spacers 810. Following the etching process, the second gate spacers 810 may be selectively removed, while leaving the first gate spacers 610 substantially intact. For example, in FIG. 12, the remaining portions of the semiconductor layers 220 and 230 of the lower portion 210A overlaid by the dummy gate structures 510 may sometimes be referred to as lower nanostructures (e.g., nanosheets) 220A and 230A, respectively. Due to the presence of the second gate spacers 810 while forming the lower nanostructures 220A and 230A, the nanostructures 220A, which are collectively formed as the channel of a lower transistor of the CFET structure 200, can have a channel length (extending along the X-direction) longer than the nanostructures 220B, which are collectively formed as the channel of an upper transistor of the CFET structure 200.

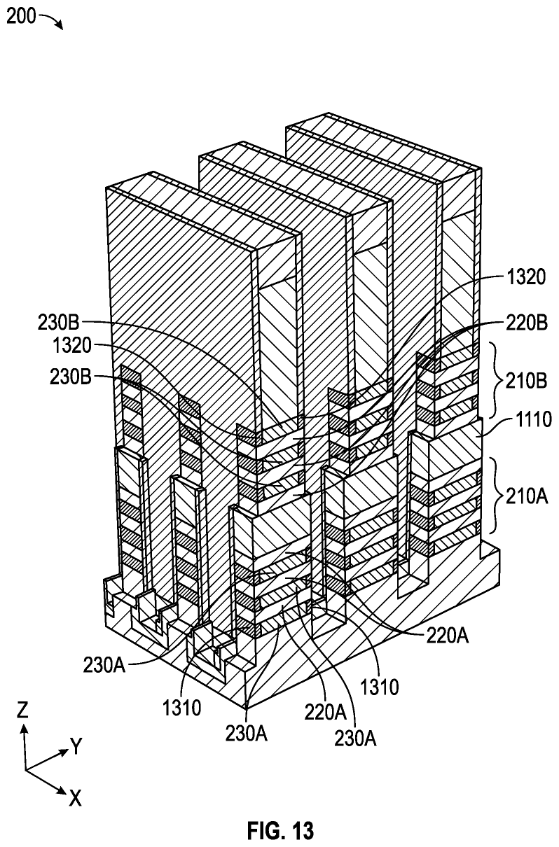

Corresponding to operation 124 of FIG. 1, FIG. 13 is a perspective view of the CFET structure 200 in which a number of first inner spacers 1310 and a number of second inner spacers 1320 are formed in the lower portion 210A and the upper portion 210B, respectively, in accordance with various embodiments.

To form the inner spacers 1310 and 1320, respective end portions of each of the lower nanostructures 230A and upper nanostructures 230B are removed. The end portions can be removed (e.g., etched) using a “pull-back” process to pull the nanostructures 230A and 230B back by a pull-back distance. In an example where the first semiconductor layers 220 include Si, and the second semiconductor layers 230 include SiGe, the pull-back process may include a hydrogen chloride (HCl) gas isotropic etch process, which etches SiGe without attacking Si. As such, the Si layers (nanostructures) 220A and 220B may remain intact during this process. Accordingly, a number of recess, each inwardly extending from exposed sidewalls of a corresponding nanostructure 220A/B, can be formed. Next, the recesses are filled with a dielectric material to form the inner spacers 1310 and 1320. For example, the inner spacers 1310 and 1320 can be formed conformally by chemical vapor deposition (CVD), or by monolayer doping (MLD) of nitride followed by spacer RIE. The inner spacer 1310 and 1320 can be deposited using, e.g., a conformal deposition process and subsequent isotropic or anisotropic etch back to remove excess spacer material. The dielectric material, used to form the inner spacers 1310 and 1320, include silicon nitride, silicoboron carbonitride, silicon carbonitride, silicon carbon oxynitride, or any other type of dielectric material (e.g., a dielectric material having a dielectric constant k of less than about 5) appropriate to the role of forming insulating gate sidewall spacers of transistors.

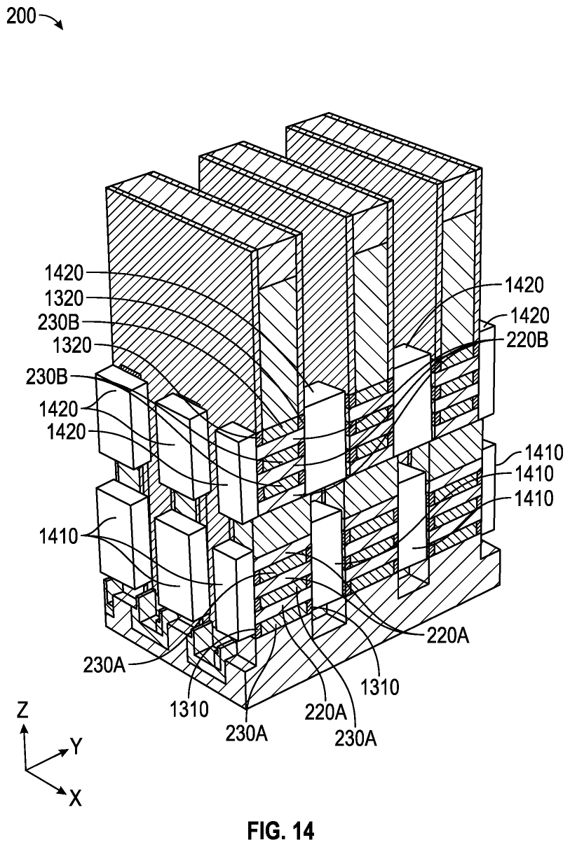

Corresponding to operation 126 of FIG. 1, FIG. 14 is a perspective view of the CFET structure 200 in which a number of first source/drain (e.g., epitaxial) structures 1410 and a number of second source/drain (e.g., epitaxial) structures 1420 are formed in the lower portion 210A and the upper portion 210B, respectively, in accordance with various embodiments.

The first source/drain structures 1410 are coupled to respective ends (along the Y-direction) of each of the lower nanostructures 220A; and the second source/drain structures 1420 are coupled to respective ends (along the Y-direction) of each of the upper nanostructures 220B. In various embodiments, any pair of the source/drain structures 1410, that are disposed on the opposite sides of the nanostructures 220A along the Y-direction, can function as source and drain terminals of the lower transistor of the CFET structure 200, and any pair of the source/drain structures 1420, that are disposed on the opposite sides of the nanostructures 220B along the Y-direction, can function as source and drain terminals of the upper transistor of the CFET structure 200. Further, the source/drain structures 1410 are separated (or otherwise isolated) from respective ends (along the Y-direction) of the nanostructures 230A with the inner spacers 1310; and the source/drain structures 1420 are separated (or otherwise isolated) from respective ends (along the Y-direction) of the nanostructures 230B with the inner spacers 1320. As will be discussed below, the nanostructures 230A and 230B will be replaced with respective portions of an active gate structure, and thus, the inner spacers 1310 can electrically isolate the channel (the nanostructures 220A) of the lower transistor from its source/drain structures 1410, and the inner spacers 1320 can electrically isolate the channel (the nanostructures 220B) of the upper transistor from its source/drain structures 1420.

The source/drain structures 1410 and 1420 may each include silicon germanium (SiGe), indium arsenide (InAs), indium gallium arsenide (InGaAs), indium antimonide (InSb), germanium arsenide (GaAs), germanium antimonide (GaSb), indium aluminum phosphide (InAIP), indium phosphide (InP), any other suitable material, or combinations thereof. The source/drain structures 1410 and 1420 may be formed using an epitaxial layer growth process on exposed ends of each of the nanostructures 220A and 220B, respectively. For example, the growth process can include a selective epitaxial growth (SEG) process, CVD deposition techniques (e.g., vapor-phase epitaxy (VPE) and/or ultra-high vacuum CVD (UHV-CVD)), molecular beam epitaxy, or other suitable epitaxial processes.

In-situ doping (ISD) may be applied to form doped epitaxial structures 1410 and 1420. In some embodiments, the first source/drain structures 1410 have a first conductive type, and the second source/drain structures 1420 have a second conductive type. For example, when the lower transistor of the CFET structure 200 is configured in n-type, the source/drain structures 1410 can be doped by implanting n-type dopants, e.g., arsenic (As), phosphorous (P), etc., into them; and when the upper transistor of the CFET structure 200 is configured in p-type, the source/drain structures 1420 can be doped by implanting p-type dopants, e.g., boron (B), etc., into them.

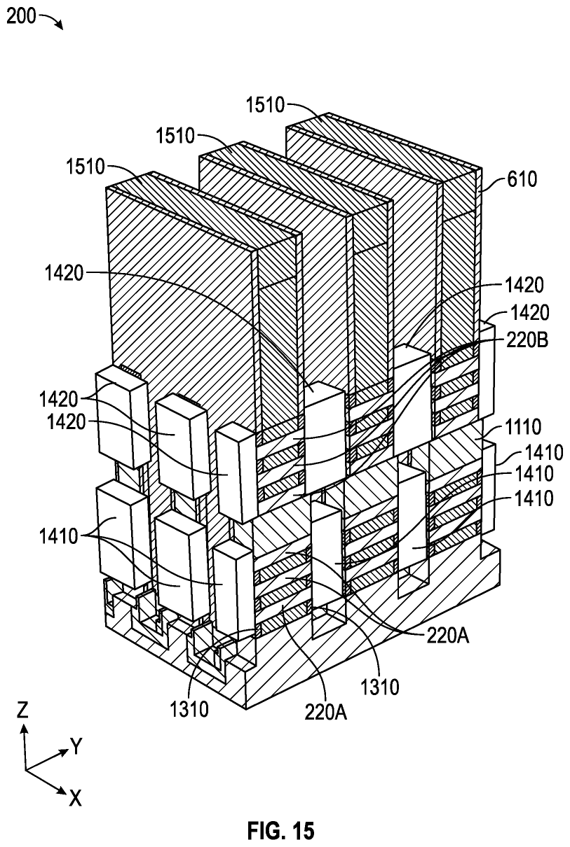

Corresponding to operation 128 of FIG. 1, FIG. 15 is a perspective view of the CFET structure 200 in which a number of active gate structures 1510 are formed, in accordance with various embodiments.

Following the formation of source/drain structures 1410 and 1420, an interlayer dielectric (ILD) is formed over the source/drain structures 1410 and 1420. Next, the dummy gate structure 510 and the nanostructures 230A and 230B (FIG. 14) may be concurrently or respectively removed. In various embodiments, the dummy gate structure 510 and the nanostructures 230A-B can be removed by applying a selective etch (e.g., a hydrochloric acid (HCl)), while leaving the nanostructures 220A-B substantially intact. After the removal of the dummy gate structure 510, a gate trench, exposing respective sidewalls of each of the nanostructures 220A-B that face the X-direction, may be formed. After the removal of the nanostructures 230A-B to further extend the gate trench, respective bottom surface and/or top surface of each of the nanostructures 220A-B may be exposed. Consequently, a full circumference of each of the nanostructures 220A-B can be exposed. Next, the active gate structures 1510 are formed to wrap around each of the nanostructures 220A-B. Specifically, each of the active gate structures 1510 can include a first portion wrapping around each of the lower nanostructures 220A, and a second portion wrapping around each of the upper nanostructures 220B. The first portion and the second portion of the active gate structures 1510 may be separated by the dielectric layer 1110. In some embodiments, the first portion of the active gate structures 1510 can function as a gate terminal of the lower transistor, and the second portion of the active gate structures 1510 can function as a gate terminal of the upper transistor.

The active gate structure 1510 includes a gate dielectric and a gate metal, in some embodiments. The gate dielectric can wrap around each of the nanostructures 220A-B, e.g., the top and bottom surfaces and sidewalls facing the X-direction). The gate dielectric may be formed of different high-k dielectric materials or a similar high-k dielectric material. Example high-k dielectric materials include a metal oxide or a silicate of Hf, Al, Zr, La, Mg, Ba, Ti, Pb, and combinations thereof. The gate dielectric may include a stack of multiple high-k dielectric materials. The gate dielectric can be deposited using any suitable method, including, for example, molecular beam deposition (MBD), atomic layer deposition (ALD), PECVD, and the like. In some embodiments, the gate dielectric may optionally include a substantially thin oxide (e.g., SiOx) layer, which may be a native oxide layer formed on the surface of each of the nanostructures 220A-B.

The gate metal can wrap around each of the nanostructures 220A-B with the gate dielectric disposed therebetween. Specifically, the gate metal can include a number of gate metal sections abutted to each other along the Z-direction. Each of the gate metal sections can extend not only along a horizontal plane (e.g., the plane expanded by the −X direction and the −Y direction), but also along a vertical direction (e.g., the Z-direction). As such, two adjacent ones of the gate metal sections can adjoin together to wrap around a corresponding one of the nanostructures 220A-B, with the gate dielectric disposed therebetween.

The gate metal may include a stack of multiple metal materials. For example, the gate metal may be a p-type work function layer, an n-type work function layer, multi-layers thereof, or combinations thereof. The work function layer may also be referred to as a work function metal. Example p-type work function metals that may include TiN, TaN, Ru, Mo, Al, WN, ZrSi₂, MoSi₂, TaSi₂, NiSi₂, WN, other suitable p-type work function materials, or combinations thereof. Example n-type work function metals that may include Ti, Ag, TaAl, TaAlC, TiAlN, TaC, TaCN, TaSiN, Mn, Zr, other suitable n-type work function materials, or combinations thereof. A work function value is associated with the material composition of the work function layer, and thus, the material of the work function layer is chosen to tune its work function value so that a target threshold voltage Vt is achieved in the device that is to be formed. The work function layer(s) may be deposited by CVD, physical vapor deposition (PVD), ALD, and/or other suitable process.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A semiconductor device, comprising:
a plurality of first nanostructures extending along a first lateral direction with a first length, and spaced from one another along a vertical direction;
a plurality of second nanostructures extending along the first lateral direction with a second length, and spaced from one another along the vertical direction; and
a dielectric layer interposed between the plurality of first nanostructures and the plurality of second nanostructures along the vertical direction,
wherein the second length is different from the first length.

2. The semiconductor device of claim 1, further comprising a gate structure extending along a second lateral direction perpendicular to the first lateral direction.

3. The semiconductor device of claim 2, wherein the gate structure includes a first portion wrapping around each of the plurality of first nanostructures and a second portion wrapping around each of the plurality of second nanostructures.

4. The semiconductor device of claim 2, wherein, along the vertical direction, the dielectric layer is interposed between the first portion of the gate structure and second portion of the gate structure.

5. The semiconductor device of claim 1, wherein, along the vertical direction, the dielectric layer is interposed between a topmost one of the plurality of first nanostructures and a bottommost one of the plurality of second nanostructures.

6. The semiconductor device of claim 4, wherein the first length is longer than the second length.

7. The semiconductor device of claim 1, further comprising:
a pair of first source/drain structures coupled to ends of the each of the first nanostructures along the first lateral direction, respectively; and
a pair of second source/drain structures coupled to ends of the each of the second nanostructures along the first lateral direction, respectively.

8. The semiconductor device of claim 7, wherein the first source/drain structures have a first conductive type, and the second source/drain structures have a second conductive type.

9. A semiconductor device, comprising:
a first transistor having a first conductive type and comprising a plurality of first nanostructures extending along a first lateral direction with a first length; and
a second transistor having a second conductive type and comprising a plurality of second nanostructures extending along the first lateral direction with a second length,
wherein the second transistor is disposed over the first transistor along a vertical direction, and the second length is shorter than the first length.

10. The semiconductor device of claim 9, wherein the first transistor and the second transistor share a gate structure extending along a second lateral direction perpendicular to the first lateral direction.

11. The semiconductor device of claim 10, wherein the gate structure includes a first portion wrapping around each of the plurality of first nanostructures and a second portion wrapping around each of the plurality of second nanostructures.

12. The semiconductor device of claim 11, further comprising a dielectric layer interposed between the first transistor and the second transistor along the vertical direction.

13. The semiconductor device of claim 12, wherein, along the vertical direction, the dielectric layer is interposed between the first portion of the gate structure and second portion of the gate structure.

14. The semiconductor device of claim 12, wherein, along the vertical direction, the dielectric layer is interposed between a topmost one of the plurality of first nanostructures and a bottommost one of the plurality of second nanostructures.

15. The semiconductor device of claim 9, further comprising:
a pair of first source/drain structures coupled to ends of the each of the first nanostructures along the first lateral direction, respectively; and
a pair of second source/drain structures coupled to ends of the each of the second nanostructures along the first lateral direction, respectively.

16. The semiconductor device of claim 15, wherein the first source/drain structures have the first conductive type, and the second source/drain structures have the second conductive type.

17. A method for fabricating semiconductor devices, comprising:
forming a stack including a first portion, a second portion, and a third portion arranged on top of one another,
wherein the first portion includes a plurality of first layers having a first semiconductor material and a plurality of second layers having a second semiconductor material alternately arranged on top of one another, the second portion includes an isolation layer having the second semiconductor material, and the third portion includes a plurality of third layers having the first semiconductor material and a plurality of fourth layers having the second semiconductor material alternately arranged on top of one another, and
wherein the first layers, the second layers, the isolation layer, the third layers, and the fourth layers extend along a first lateral direction;
forming a dummy gate structure to straddle the stack, wherein the dummy gate structure extends along a second lateral direction perpendicular to the first lateral direction;
selectively etching the isolation layer, while leaving a first portion of each of the first, second, third, and fourth layers that is overlaid by the dummy gate structure substantially intact; and
replacing the dummy gate structure with an active gate structure.

18. The method of claim 17, subsequently to the step of forming a dummy gate structure and prior to the step of selectively etching the isolation layer, further comprising:
forming a first gate spacer extending along sidewalls of the dummy gate structure;
removing second portions of each of the third and fourth layers that extend beyond the first gate spacers along the first lateral direction; and
forming a second gate spacer extending along the first gate spacer.

19. The method of claim 18, subsequently to the step of selectively etching the isolation layer, further comprising:
depositing a dielectric material;
removing second portions of each of the first and second layers that extend beyond the second gate spacer along the first lateral direction; and
removing the second gate spacer.

20. The method of claim 17, wherein the step of replacing the dummy gate structure with an active gate structure further comprises removing the second layers and the fourth layers while leaving the first layers and the third layers substantially intact, such that the active gate structure wraps around each of the first layers and the third layers.
